(19) United States
(12) Patent Application Publication
(10) Pub. No.: US 2026/0090018 A1
(43) Pub. Date: Mar. 26, 2026

(54) Thin Film Transistor, Manufacturing Method of Thin Film Transistor and Display Apparatus Comprising the Same

(71) Applicant: LG Display Co., Ltd., Seoul (KR)

(72) Inventors: Jinwon Jung, Paju-si (KR); Jaeman Jang, Paju-si (KR)

(21) Appl. No.: 19/072,447

(22) Filed: Mar. 6, 2025

(30) Foreign Application Priority Data
Sep. 26, 2024 (KR) 10-2024-0130631

(51) Int. Cl. H10D 30/67; H10D 30/01; H10D 62/60; H10D 86/01; H10D 86/40; H10D 86/60

(52) U.S. Cl. CPC H10D 30/6731; H10D 30/0314; H10D 62/60; H10D 86/0251; H10D 86/423; H10D 86/60; H10D 86/441

(57) ABSTRACT

A thin film transistor includes an active layer comprising: a first region; a second region on one side of the first region; and a third region on another side of the first region, wherein when a direction connecting source and drain electrodes is a first direction, the first, second, and third regions are along a second direction, and the first region comprises: a channel portion overlapping with the gate electrode; a first connecting portion on one side of the channel portion; And a second connecting portion on the other side of the channel portion, wherein the second region includes first and second dopant reduction portions, the third region includes third and fourth dopant reduction portions, and in a plane view, the gate electrode is inside the active layer, and the first, second, third, and fourth dopant reduction portions each have a higher resistivity than the first and second connecting portions.

### CROSS-REFERENCE TO RELATED APPLICATION

This application claims the benefit of priority of the Republic of Korea Patent Application No. 10-2024-0130631 filed on Sep. 26, 2024, which is hereby incorporated by reference in its entirety.

### BACKGROUND

### Field

The present disclosure relates to a thin film transistor, a method for manufacturing a thin film transistor, and a display device including a thin film transistor.

### Discussion of the Related Art

Transistors are widely used as switching devices or driving devices in the field of electronic devices. In particular, thin film transistors are widely used as switching devices in display devices such as liquid crystal display devices or organic light emitting devices because they can be manufactured on glass or plastic substrates.

Thin film transistors can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

In the case of oxide semiconductor materials of oxide semiconductor thin film transistors, the properties of the area in contact with the etchant change due to a reaction with the etchant during the etching process for pattern formation.

At this time, a problem of current concentration at the edge may occur due to the edge effect, in which the flow of current increases in the area in contact with the etchant.

### SUMMARY

One embodiment of the present disclosure provides a thin film transistor in which the edge effect for the active layer is reduced by disposing the gate electrode within the active layer and increasing the resistivity of the second region and the third region.

Another embodiment of the present disclosure provides a thin film transistor in which a fringe field between the first connecting portion and the second connecting portion is reduced by disposing the first connecting portion and the second connecting portion between the second region and the third region, respectively, and increasing the resistivity of the second region and the third region.

In accordance with an embodiment of the present disclosure, the above and other objects can be accomplished by the provision of a thin film transistor comprises: an active layer; a gate electrode overlapping at least partly with the active layer; and a source electrode and a drain electrode connected to the active layer and disposed to be spaced apart from each other, wherein the active layer comprises: a first region; a second region disposed on one side of the first region; and a third region disposed on the other side of the first region, wherein when a direction connecting the source electrode and the drain electrode is a first direction and a direction perpendicular to the first direction is a second direction, the first region, the second region, and the third region are disposed along the second direction, and the first region comprises: a channel portion overlapping with the gate electrode; a first connecting portion disposed on one side of the channel portion; And a second connecting portion disposed on the other side of the channel portion, wherein the second region includes a first dopant reduction portion and a second dopant reduction portion, the third region includes a third dopant reduction portion and a fourth dopant reduction portion, and in a plane view, the gate electrode is disposed inside the active layer, and the first dopant reduction portion, the second dopant reduction portion, the third dopant reduction portion, and the fourth dopant reduction portion each have a higher resistivity than the first connecting portion and the second connecting portion.

The second region includes a first semiconductor portion disposed between the first dopant reduction portion and the second dopant reduction portion, the third region includes a second semiconductor portion disposed between the third dopant reduction portion and the fourth dopant reduction portion, and the first semiconductor portion and the second semiconductor portion may have higher resistivity compared to the first dopant reduction portion, the second dopant reduction portion, the third dopant reduction portion, and the fourth dopant reduction portion, respectively.

In a plane view, the gate electrode overlaps the first region and can be positioned between the first semiconductor portion and the second semiconductor portion.

In a plane view, the first connecting portion may be disposed between the first dopant reduction portion and the third dopant reduction portion, and in a plane view, the second connecting portion may be disposed between the second dopant reduction portion and the fourth dopant reduction portion.

The first dopant reduction portion and the second dopant reduction portion are spaced apart from each other with the first semiconductor portion therebetween, the first dopant reduction portion, the first semiconductor portion, and the second dopant reduction portion are disposed along the first direction, the third dopant reduction portion and the fourth dopant reduction portion are spaced apart from each other with the second semiconductor portion therebetween, and the third dopant reduction portion, the second semiconductor portion, and the fourth dopant reduction portion can be disposed along the first direction.

A gate insulating film disposed on the active layer; and a first interlayer insulating film disposed on the gate insulating film and may further include a trench surrounded by the gate insulating film and the first interlayer insulating film.

The trench can be formed by simultaneous etching of the gate insulating film and the first interlayer insulating film.

The gate electrode is disposed within the trench, and the trench may extend from the first connecting portion to the second connecting portion in a plane view.

At least a portion of the second region in a plane view overlaps the gate insulating film and the first interlayer insulating film, at least a portion of the third region in a plane view overlaps the gate insulating film and the first interlayer insulating film, and the first region in a plane view can overlap the trench.

The distance between the upper surface of the first region and the upper surface of the gate insulating film overlapping the first region may be shorter than the distance between the upper surface of the second region and the upper surface of the gate insulating film overlapping the second region.

In a plane view, the gate electrode may not overlap with the second region and the third region.

The dopant ion concentrations of the first dopant reduction portion, the second dopant reduction portion, the third dopant reduction portion, and the fourth dopant reduction portion may be lower than the dopant ion concentrations of the first connecting portion and the second connecting portion.

The thin film transistor further includes a gate connection electrode disposed on the gate electrode and in contact with the gate electrode, and the gate electrode can be connected to a gate line through the gate connection electrode.

Another embodiment of the present disclosure provides a method for manufacturing a thin film transistor, comprising: forming an active material layer; sequentially forming a gate insulating film and a first interlayer insulating film on the active material layer; simultaneously etching the gate insulating film and the first interlayer insulating film to form a trench; forming a gate electrode material layer on the trench and the first interlayer insulating film; doping the active material layer with dopant ions using the gate electrode material layer as a mask to form an active layer; etching the gate electrode material layer to form a gate electrode; and forming a second interlayer insulating film on the gate electrode, wherein the gate electrode is disposed inside the active layer in a plane view.

The active layer includes a first region; a second region disposed on one side of the first region; and a third region disposed on the other side of the first region, wherein the first region includes a channel portion overlapping the gate electrode; a first connecting portion disposed on one side of the channel portion; and a second connecting portion disposed on the other side of the channel portion, wherein the second region includes a first dopant reduction portion, a second dopant reduction portion, and a first semiconductor portion disposed between the first dopant reduction portion and the second dopant reduction portion, and wherein the third region includes a third dopant reduction portion, a fourth dopant reduction portion, and a second semiconductor portion disposed between the third dopant reduction portion and the fourth dopant reduction portion, wherein the first dopant reduction portion, the second dopant reduction portion, the third dopant reduction portion, and the fourth dopant reduction portion may have higher resistivity than the first connecting portion and the second connecting portion, respectively.

Another embodiment of the present disclosure provides a display device including the thin film transistor.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plane view of a thin film transistor according to one embodiment of the present disclosure.

FIG. 2 is a cross-sectional view taken along line I-I′ of FIG. 1 according to one embodiment of the present disclosure.

FIG. 3 is a cross-sectional view taken along line II-II′ of FIG. 1 according to one embodiment of the present disclosure.

FIG. 4 is a cross-sectional view taken along line III-III′ of FIG. 1 according to one embodiment of the present disclosure.

FIG. 5 is a plane view of a thin film transistor according to a comparative example.

FIGS. 6A to 6G are process plan views showing a manufacturing process of a thin film transistor according to one embodiment of the present disclosure.

FIGS. 7A to 7G are cross-sectional views taken along line I-I′ of FIGS. 6A to 6G according to one embodiment of the present disclosure.

FIGS. 8A to 8G are cross-sectional views taken along line II-II′ of FIGS. 6A to 6A according to one embodiment of the present disclosure.

FIG. 8H is an additional process cross-sectional view showing a manufacturing process of a thin film transistor according to one embodiment of the present disclosure.

FIGS. 9A to 9G are cross-sectional views taken along line III-III′ of FIGS. 6A to 6G according to one embodiment of the present disclosure.

FIG. 10 is a schematic diagram of a display device according to one embodiment of the present disclosure.

FIG. 11 is a circuit diagram for one pixel of FIG. 10 according to one embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath”another device may be arranged “above”another device. Therefore, an exemplary term “below or beneath” may include “below or beneath” and “above” orientations. Likewise, an exemplary term “above” or “on” may include “above” and “below or beneath”orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

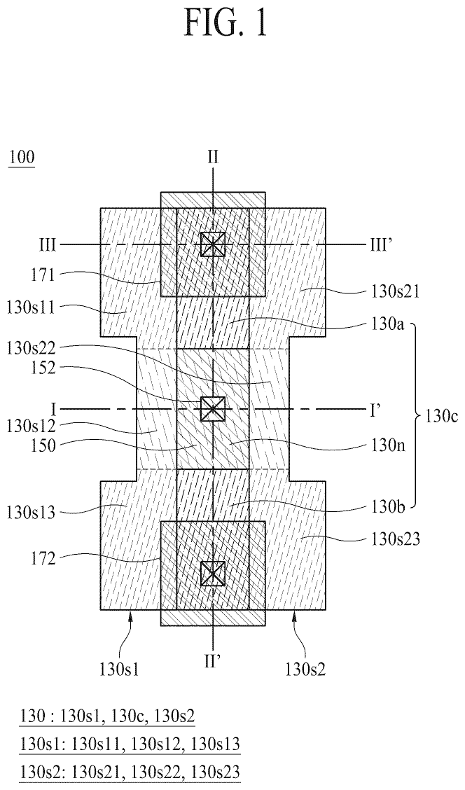

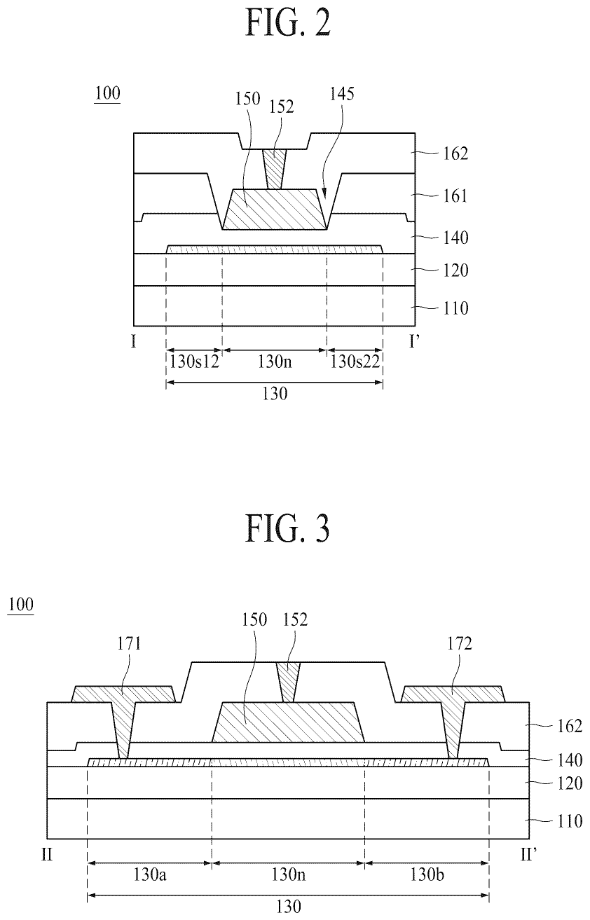

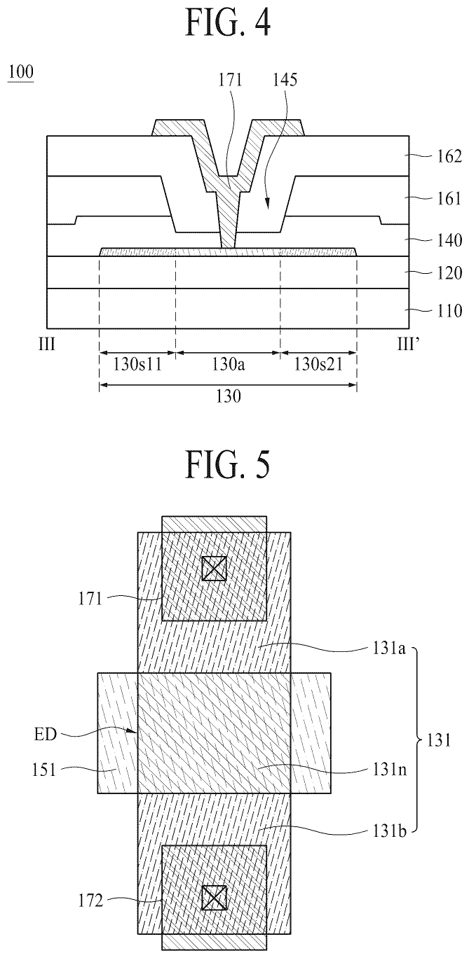

FIG. 1 is a plane view of a thin film transistor (100) according to one embodiment of the present disclosure. FIG. 2 is a cross-sectional view taken along line I-I′ of FIG. 1 according to one embodiment of the present disclosure. FIG. 3 is a cross-sectional view taken along line II-II′ of FIG. 1 according to one embodiment of the present disclosure. FIG. 4 is a cross-sectional view taken along line III-III′ of FIG. 1 according to one embodiment of the present disclosure.

Referring to FIGS. 1, 2, and 3, a thin film transistor (100) according to one embodiment of the present invention may include an active layer (130) and a gate electrode (150).

Specifically, referring to FIGS. 1 to 4, a thin film transistor (100) according to one embodiment of the present disclosure may include a base substrate (110), a buffer layer (120) on the base substrate (110), an active layer (130) on the buffer layer (120), a gate insulating film (140) on the active layer (130), a gate electrode (150), a first interlayer insulating film (161) and a second interlayer insulating film (162) on the gate insulating film (140) and a source electrode (171) and a drain electrode (172) on the second interlayer insulating film (162).

Below, components of a thin film transistor (100) according to one embodiment of the present invention are described in detail.

The base substrate (110) may be made of glass or plastic. A transparent plastic having flexible properties, such as polyimide, may be used.

When polyimide is used as the base substrate (110), considering that a high-temperature deposition process is performed on the base substrate (110), a heat-resistant polyimide that can withstand high temperatures can be used. In this case, for forming a thin film transistor, processes such as deposition and etching can be performed while the polyimide substrate is disposed on a carrier substrate made of a highly durable material such as glass.

Although not shown in the drawing, a light shielding layer (not shown) may be disposed on the base substrate (110).

A light blocking layer (not shown) may be disposed between the base substrate (110) and the buffer layer (120). The light blocking layer (not shown) may overlap with the active layer (130). Specifically, the light blocking layer (not shown) may overlap with the channel portion (130n). The light blocking layer (not shown) may block light incident from the outside, thereby protecting the channel portion (130n).

The light shielding layer (not shown) can be made of a material having light shielding properties. The light shielding layer (not shown) can include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), and iron (Fe). According to one embodiment of the present invention, the light shielding layer (not shown) can have electrical conductivity.

Referring to FIGS. 2 to 4, a buffer layer (120) may be disposed on a base substrate (110).

The buffer layer (120) is formed on the base substrate (110) and may be formed of an inorganic material or an organic material. For example, it may include an insulating oxide such as silicon oxide (SiOx) or aluminum oxide (Al2O3).

The buffer layer (120) protects the active layer (130) by blocking impurities such as moisture and oxygen flowing in from the base substrate (110) and serves to flatten the upper portion of the base substrate (110) and can be formed as a single layer or multiple layers.

When the buffer layer (120) is multi-layered, each of the multi-layers can be formed of different materials.

Referring to FIGS. 2 to 4, an active layer (130) may be disposed on a buffer layer (120).

The active layer (130) may include a first region (130c), a second region (130s1), and a third region (130s2).

Specifically, the second region (130s1) may be disposed on one side of the first region (130c), and the third region (130s2) may be disposed on the other side of the first region (130c). More specifically, the first region (130c) may be disposed between the second region (130s1) and the third region (130s2). For example, in a plane view, the channel portion (130n), the first connecting portion (130a), and the second connecting portion (130b) are respectively disposed between the second region (130s1) and the third region (130s2). For example, when the direction connecting the source electrode (171) and the drain electrode (172) is referred to as the first direction, and the direction perpendicular to the first direction is referred to as the second direction, the first region (130c), the second region (130s1), and the third region (130s2) are disposed along the second direction. Specifically, the first region (130c), the second region (130s1), and the third region (130s2) are disposed parallel along the second direction in a plane view.

The first region (130c) may include a channel portion (130n) that overlaps the gate electrode (150) in a plane view, a first connecting portion (130a) that does not overlap the gate electrode (150) in a plane view and is connected to one side of the channel portion (130n), and a second connecting portion (130b) that does not overlap the gate electrode (150) in a plane view and is connected to the other side of the channel portion (130n).

According to one embodiment of the present disclosure, the first connecting portion (130a) and the second connecting portion (130b) are spaced apart from each other with the channel portion (130n) therebetween.

According to one embodiment of the present disclosure, the second region (130s1) may include a first dopant reduction portion (130s11), a second dopant reduction portion (130s13), and a first semiconductor portion (130s12) disposed between the first dopant reduction portion (130s11) and the second dopant reduction portion (130s13).

For example, FIG. 1 illustrates a first dopant reduction section (130s11) and a second dopant reduction section (130s13) being spaced apart from each other with the first semiconductor section (130s12) interposed therebetween.

According to one embodiment of the present disclosure, the third region (130s2) may include a third dopant reduction portion (130s21), a fourth dopant reduction portion (130s23), and a second semiconductor portion (130s22) disposed between the third dopant reduction portion (130s21) and the fourth dopant reduction portion (130s23).

For example, FIG. 1 illustrates a third dopant reduction section (130s21) and a fourth dopant reduction section (130s23) being spaced apart from each other with the second semiconductor section (130s22) interposed therebetween.

According to one embodiment of the present disclosure, when a direction parallel to a straight line connecting the first connecting portion (130a) and the second connecting portion (130b) at the shortest distance is referred to as a first direction, the first dopant reduction portion (130s11), the first semiconductor portion (130s12), and the second dopant reduction portion (130s13) may be disposed in parallel along the first direction. In this case, the first direction may also be referred to as a direction connecting the source electrode (171) and the drain electrode (172).

According to one embodiment of the present disclosure, the third dopant reduction portion (130s21), the second semiconductor portion (130s22), and the fourth dopant reduction portion (130s23) can be disposed in parallel along the first direction.

According to one embodiment of the present disclosure, the first connecting portion (130a) is disposed in a plane view between the first dopant reduction portion (130s11) and the third dopant reduction portion (130s21), and the second connecting portion (130b) is disposed in a plane view between the second dopant reduction portion (130s13) and the fourth dopant reduction portion (130s23).

For example, FIG. 1 illustrates a first dopant reduction portion (130s11) and a third dopant reduction portion (130s21) being spaced apart from each other with a first connecting portion (130a) therebetween. FIG. 1 also illustrates a second dopant reduction portion (130s13) and a fourth dopant reduction portion (130s23) being spaced apart from each other with a second connecting portion (130b) therebetween.

According to one embodiment of the present disclosure, the active layer (130) may be formed of a semiconductor material. The active layer (130) may include an oxide semiconductor material.

The oxide semiconductor material may be, for example, an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material. However, one embodiment of the present invention is not limited thereto, and the active layer 130 may be made of other oxide semiconductor materials known in the art.

The first connecting portion (130a) and the second connecting portion (130b) can be formed by selectively conductorized for the active layer (130) made of a semiconductor material. According to one embodiment of the present invention, imparting conductivity to a specific portion of the active layer (130) so that it can function as a conductor is called selective conductorization.

For example, the active layer (130) can be selectively conductorized by ion doping. As a result, the first connecting portion (130a) and the second connecting portion (130b) can be formed. However, one embodiment of the present invention is not limited thereto, and the active layer (130) can be selectively conductorized by other methods known in the art.

The first connecting portion (130a) and the second connecting portion (130b) do not overlap with the gate electrode (150). The first connecting portion (130a) and the second connecting portion (130b) have superior electrical conductivity and high mobility compared to the channel portion (130n). Therefore, the first connecting portion (130a) and the second connecting portion (130b) can each function as wiring.

According to one embodiment of the present disclosure, the active layer (130) may have a multilayer structure. For example, although not shown in the drawing, the active layer (130) may include a first active layer and a second active layer.

The first active layer and the second active layer may include the same semiconductor material or may include different semiconductor materials.

According to one embodiment of the present disclosure, the thin film transistor (100) may further include a gate insulating film (140) between the active layer (130) and the gate electrode (150). Specifically, the gate insulating film (140) may cover the entire upper surface of the active layer (130). FIGS. 2 to 4 illustrate a configuration in which the gate insulating film (140) covers the entire upper surface of the active layer (130).

The gate insulating film (140) may include at least one of silicon oxide, silicon nitride, and metal oxide. The gate insulating film (140) may have a single film structure or a multilayer film structure. The gate insulating film (140) protects the channel portion (130n).

Referring to FIGS. 1 to 4, a gate electrode (150) is disposed on a gate insulating film (140). The gate electrode (150) overlaps with a channel portion (130n) of the active layer (130).

The gate electrode (150) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (150) may also have a multilayer film structure including at least two conductive films having different physical properties.

According to one embodiment of the present disclosure, the gate electrode (150) is disposed inside the active layer (130) in a plane view. Specifically, the gate electrode (150) is disposed spaced apart from the outermost part of the active layer (130) in a plane view. For example, the gate electrode (150) is disposed between the second region (130s1) and the third region (130s2) in a plane view. For example, the gate electrode (150) overlaps the first region (130c). More specifically, the gate electrode (150) overlaps the channel portion (130n) of the first region (130c).

According to one embodiment of the present disclosure, the gate electrode (150) may not overlap the second region (130s1) and the third region (130s2).

According to one embodiment of the present disclosure, the gate electrode (150) may overlap the first region (130c) in a plane view and be positioned between the first semiconductor portion (130s12) and the second semiconductor portion (130s22).

According to one embodiment of the present disclosure, the gate electrode (150) has an island shape.

Referring to FIGS. 2 to 4, a first interlayer insulating film (161) is disposed on a gate insulating film (140). The first interlayer insulating film (161) is an insulating layer made of an insulating material. The first interlayer insulating film (161) may be made of an organic material, an inorganic material, or a laminate of an organic material layer and an inorganic material layer.

According to one embodiment of the present disclosure, the thin film transistor (100) may further include a trench (145) surrounded by a gate insulating film (140) and a first interlayer insulating film (161). According to one embodiment of the present invention, the trench (145) means a region formed by simultaneously patterning the gate insulating film (140) and the first interlayer insulating film (161). For example, the trench (145) is formed by simultaneously etching the gate insulating film (140) and the first interlayer insulating film (161).

According to one embodiment of the present disclosure, the trench (145) is formed in the first region (130c) of the active layer (130). For example, according to FIGS. 1 to 4, the trench (145) overlaps the first region (130c) in a plane view. For example, the trench (145) extends from the first connecting portion (130a) of the first region (130c) to the second connecting portion (130b) in a plane view. For example, the trench (145) extends from the first connecting portion (130a) of the first region (130c) to the second connecting portion (130b) in a plane view.

According to one embodiment of the present disclosure, the distance between the upper surface of the first region (130c) and the upper surface of the gate insulating film (140) overlapping the first region (130c) may be shorter than the distance between the upper surface of the second region (130s1) and the upper surface of the gate insulating film (140) overlapping the second region (130s1).

For example, referring to FIGS. 2 and 4, due to the trench (145) structure, the thickness of the gate insulating film (140) disposed in the first region (130c) of the active layer (130) may be smaller than the thickness of the gate insulating film (140) disposed in the second region (130s1) or the third region (130s2).

According to one embodiment of the present disclosure, at least a portion of the second region (130s1) of the active layer (130) overlaps with the gate insulating film (140) and the first interlayer insulating film (161), and at least a portion of the third region (130s2) of the active layer (130) overlaps with the gate insulating film (140) and the first interlayer insulating film (161).

FIGS. 2 and 4 illustrate a portion of the second region (130s1) and the third region (130s2) overlapping the gate insulating film (140) and the first interlayer insulating film (161) simultaneously.

According to one embodiment of the present disclosure, the gate electrode (150) is disposed within the trench (145).

According to one embodiment of the present disclosure, when the active layer (130) is selectively conductorized by ion doping, which is an example of selective conductorization, the channel portion (130n) of the active layer (130) is covered by the gate electrode (150), so conductorization does not proceed in the channel portion (130n).

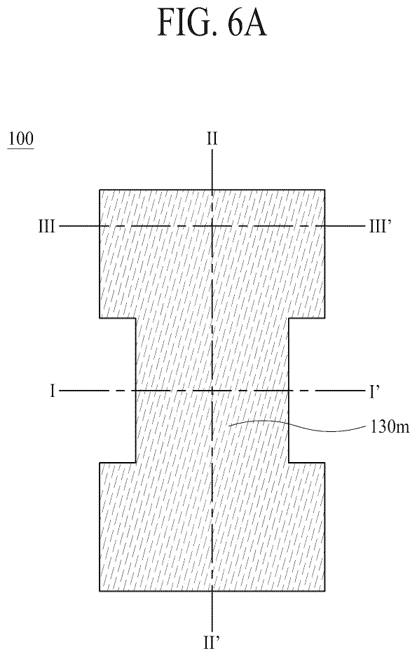

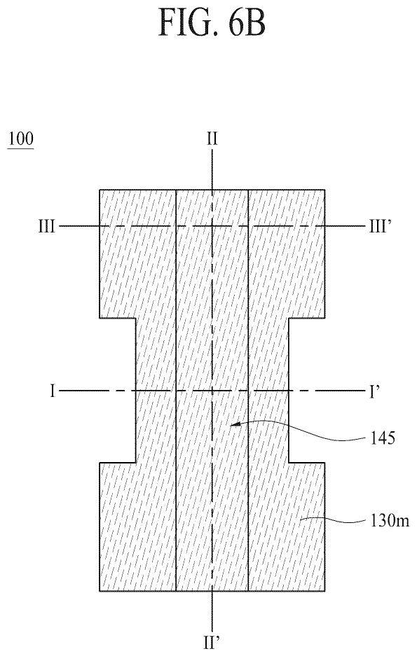

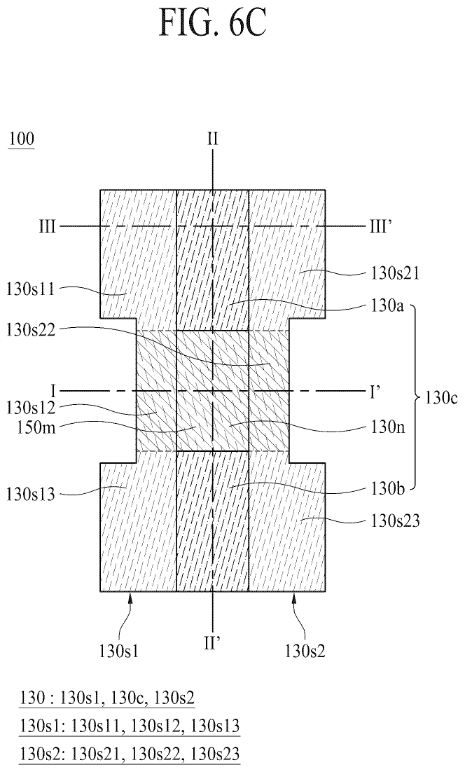

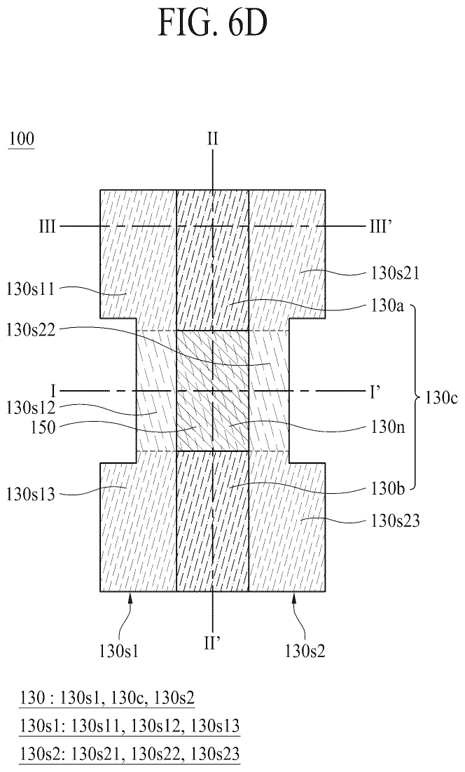

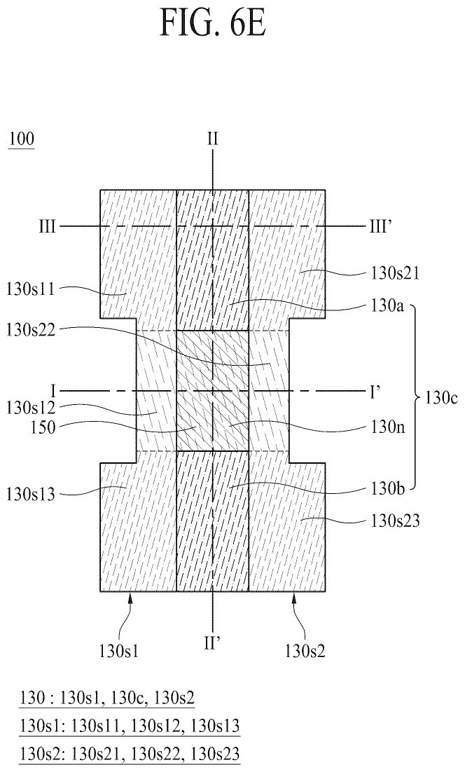

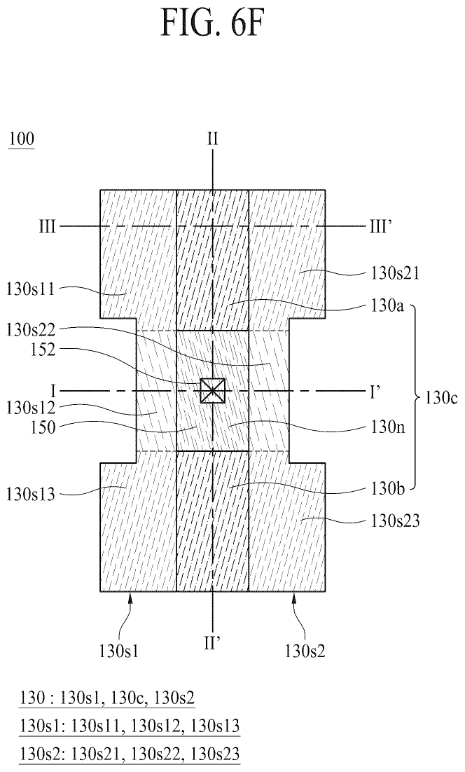

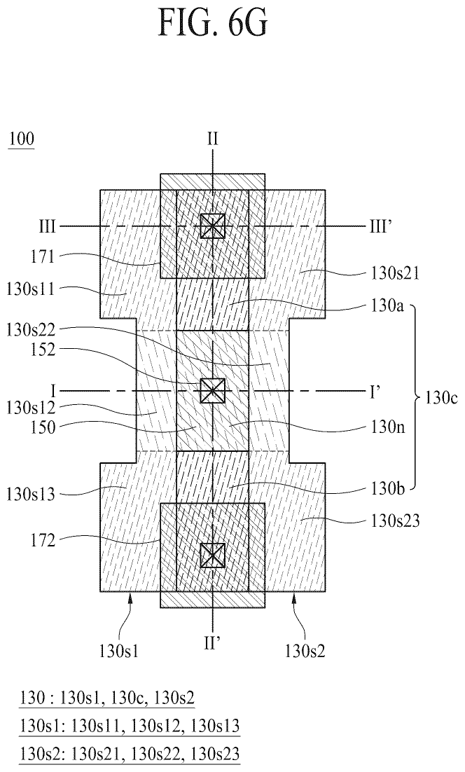

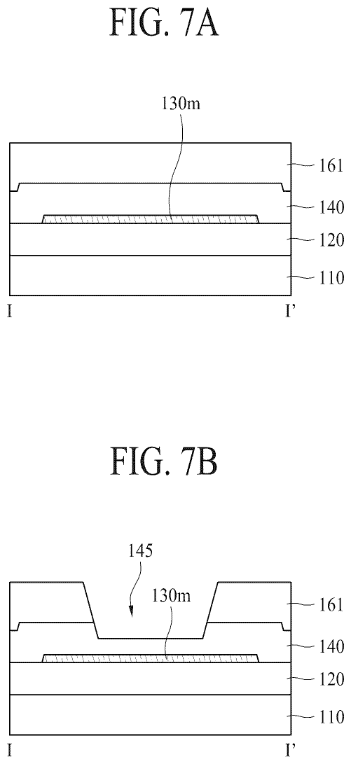

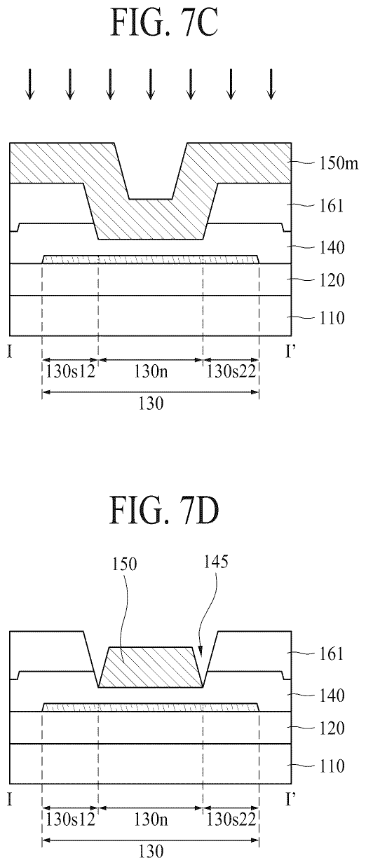

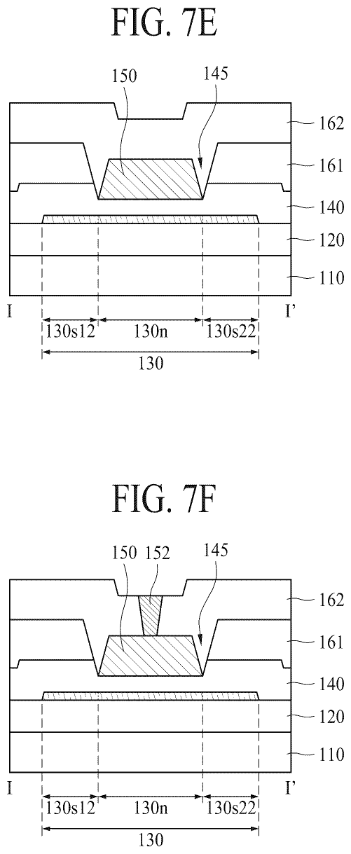

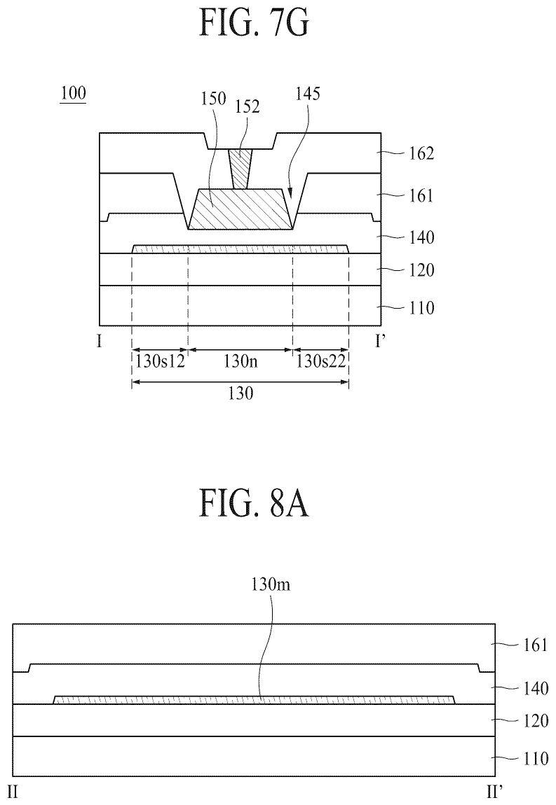

According to one embodiment of the present disclosure, when the active layer (130) is selectively conductorized by ion doping, which is an example of selective conductorization, the first semiconductor portion (130s12) and the second semiconductor portion (130s22) of the active layer (130) are covered by the gate electrode material layer (150m), so that conductorization does not proceed in the first semiconductor portion (130s12) and the second semiconductor portion (130s22) (see FIGS. 6c and 7c). That is, the first semiconductor portion (130s12) and the second semiconductor portion (130s22) may have higher resistivity than the first dopant reduction portion (130s11), the second dopant reduction portion (130s13), the third dopant reduction portion (130s21), and the fourth dopant reduction portion (130s23), respectively.

In addition, since the first dopant reduction portion (130s11), the second dopant reduction portion (130s13), the third dopant reduction portion (130s21), and the fourth doped portion (130s23) of the active layer (130) overlap or are covered by the gate insulating film (140) and the first interlayer insulating film (161), the dopant ion concentrations of the second region (130s1) and the third region (130s2) may be lower than the dopant ion concentrations of the first connecting portion (130a) and the second connecting portion (130b).

Due to this, the resistivity of the first dopant reduction portion (130s11), the second dopant reduction portion (130s13), the third dopant reduction portion (130s21), and the fourth dopant reduction portion (130s23) may be higher than the resistivity of the first connecting portion (130a) and the second connecting portion (130b). In addition, the resistivity of the first dopant reduction portion (130s11), the second dopant reduction portion (130s13), the third dopant reduction portion (130s21), and the fourth dopant reduction portion (130s23) may be lower than the resistivity of the channel portion (130n).

In general, in the case of an active layer made of an oxide semiconductor, the properties of the area in contact with the etchant may change due to a reaction with the etchant during an etching process for forming a pattern of the active layer.

At this time, a problem may arise in which an edge effect occurs, in which the flow of current increases in the edge region of the active layer in contact with the etchant.

As a result, when the active layer has a small width (W), the threshold voltage (Vth) of the thin film transistor may shift in the negative (−) direction, which may deteriorate the operating stability of the thin film transistor.

According to one embodiment of the present disclosure, by disposing the gate electrode (150) to overlap the channel portion (130n), the generation of an abnormal current that may occur in the edge region of the active layer (130) can be suppressed or prevented. For example, by disposing the gate electrode (150) inside the active layer (130), the generation of an abnormal current that may occur in the edge region of the active layer (130) can be suppressed or prevented. Specifically, the edge effect in which the flow of current increases in the region in contact with the etchant can be suppressed or prevented.

As a result, even if the active layer (130) has a small width (W), the threshold voltage (Vth) of the thin film transistor (100) can be controlled to move in the negative (−) direction, thereby improving the driving stability of the thin film transistor (100).

In addition, by disposing a first dopant reduction portion (130s11) and a third dopant reduction portion (130s21) having high resistivity on both sides of the first connecting portion (130a), and disposing a second dopant reduction portion (130s13) and a fourth dopant reduction portion (130s23) having high resistivity on both sides of the second connecting portion (130b), the fringe field between the first connecting portion (130a) and the second connecting portion (130b) can be reduced.

At this time, the width (W) of the active layer (130) means the length of the active layer (130) in the vertical direction connecting the first connecting portion (130a) and the second connecting portion (130b) at the shortest distance.

FIG. 5 is a plane view of a thin film transistor according to a comparative example.

Although not shown in FIG. 5, when the active layer (131) is selectively conductorized by ion doping, the first connecting portion (131a) and the second connecting portion (131b) are each covered only by the gate insulating film and are not simultaneously covered by the gate insulating film and the interlayer insulating film. Therefore, the first connecting portion (131a) and the second connecting portion (131b) of the thin film transistor shown in FIG. 5 can each be selectively conductorized by ion doping.

According to the comparative example of FIG. 5, the edge (ED) of the active layer (131) is a region that comes into contact with the etchant, and the properties of the edge (ED) of the active layer (131) may change due to a reaction with the etchant. At this time, the gate electrode (151) of the thin film transistor according to the comparative example overlaps with the edge (ED) of the active layer (131), and an abnormal current flow may occur when the thin film transistor is driven.

Unlike the thin film transistor according to the comparative example illustrated in FIG. 5, the thin film transistor according to the present disclosure can suppress or prevent the generation of an abnormal current that may occur in the edge region of the active layer (130) by disposing the gate electrode (150) inside the active layer (130).

According to one embodiment of the present disclosure, a second interlayer insulating film (162) may be further included on the first interlayer insulating film (161). The second interlayer insulating film (162) is an insulating layer made of an insulating material. The second interlayer insulating film (162) may be made of an organic material, an inorganic material, or a laminate of an organic material layer and an inorganic material layer.

The second interlayer insulating film (162) may be made of the same material as the first interlayer insulating film (161) or may be made of a different material.

Referring to FIG. 2, the second interlayer insulating film (162) can cover the entire first interlayer insulating film (161) and the gate electrode (150).

According to one embodiment of the present disclosure, a gate connection electrode (152) may be further included, which is disposed on the gate electrode (150) and is in contact with the gate electrode (150).

Referring to FIGS. 2 and 3, the gate connection electrode (152) is formed by etching the second interlayer insulating film (162).

Although not shown in the drawing, the gate electrode (150) can be connected to the gate line (GL) via the gate connection electrode (152) (see FIG. 11).

Referring to FIG. 1 and FIG. 3, a source electrode (171) and a drain electrode (172) are disposed on a second interlayer insulating film (162).

The source electrode (171) and drain electrode (172) can be made of the same material as the gate electrode (150).

The source electrode (171) and the drain electrode (172) may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The source electrode (171) and the drain electrode (172) may each have a multilayer film structure including at least two conductive films having different physical properties.

Referring to FIG. 1, FIG. 3, and FIG. 4, the source electrode (171) and the drain electrode (172) are each connected to the active layer (130) through a contact hole. Specifically, the source electrode (171) and the drain electrode (172) are connected to the active layer (130) by contacting the first connecting portion (130a) and the second connecting portion (130b). The source electrode (171) and the drain electrode (172) are disposed spaced apart from each other.

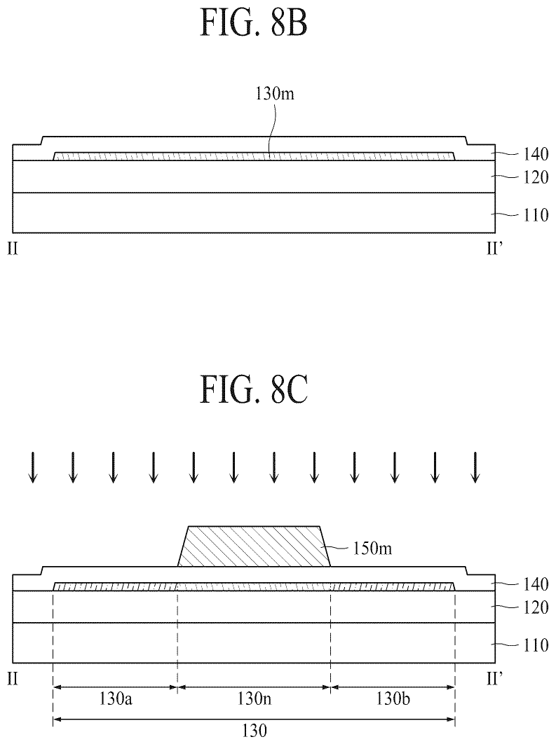

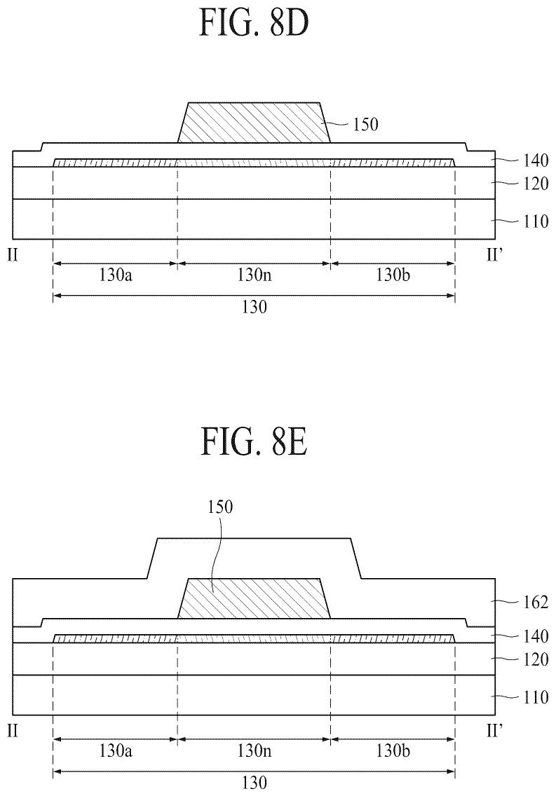

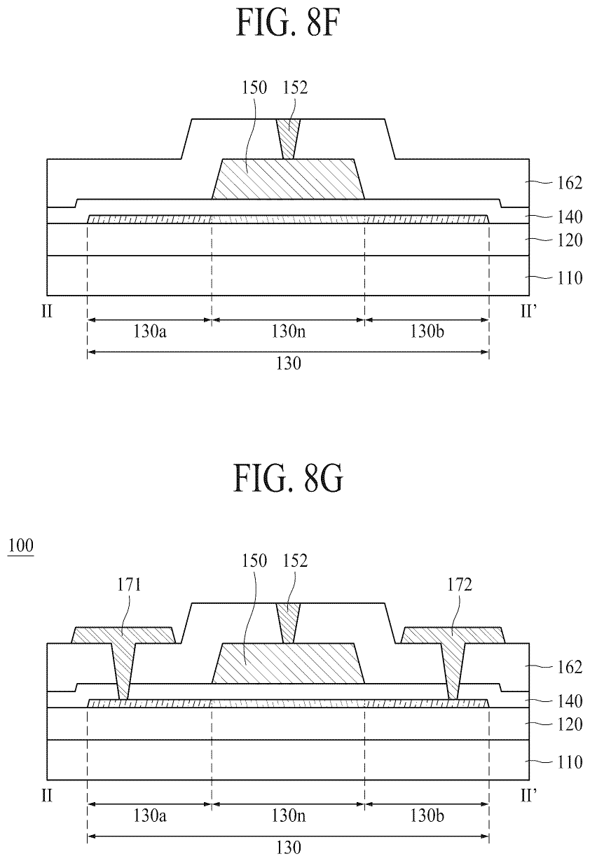

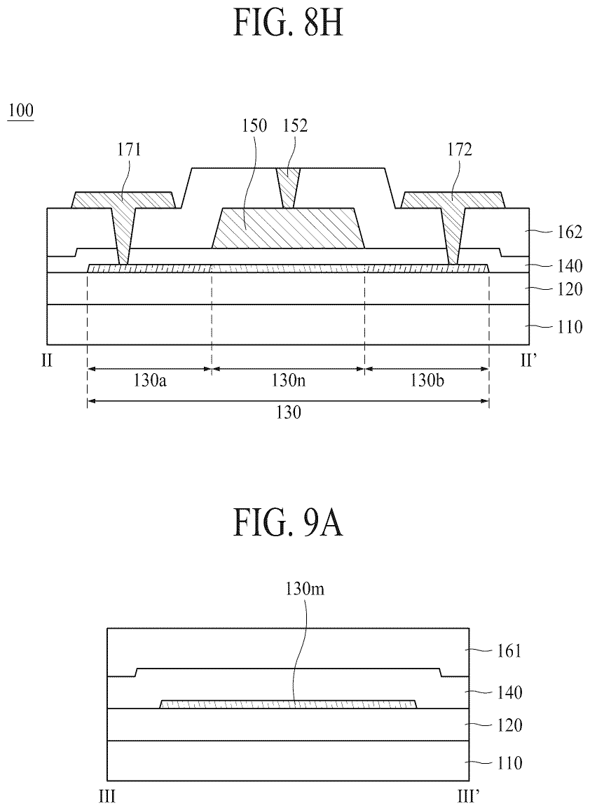

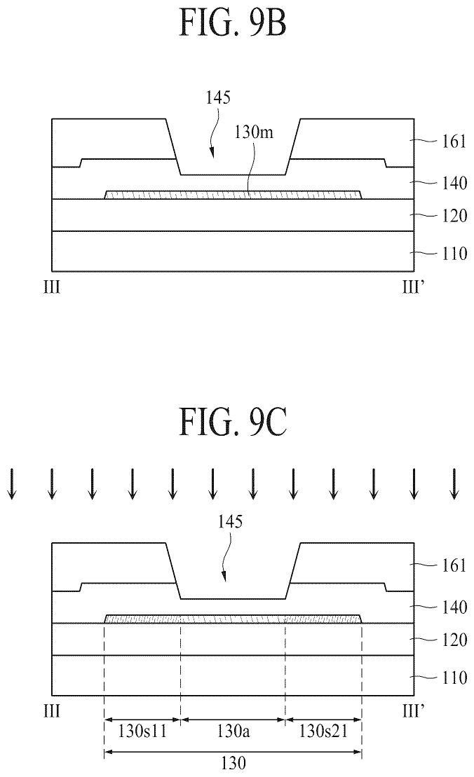

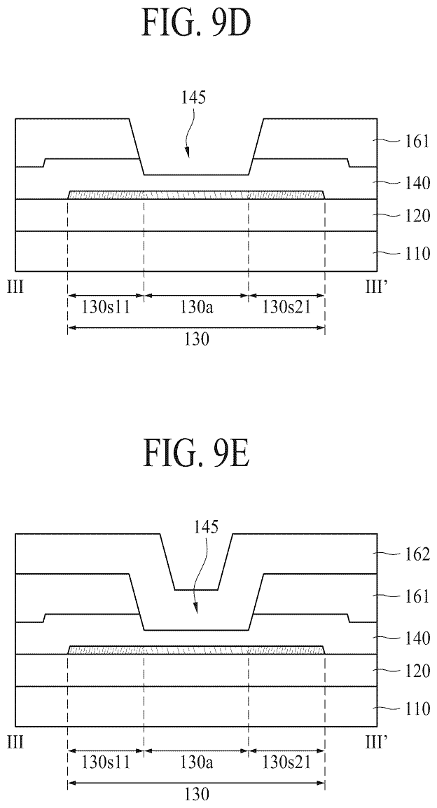

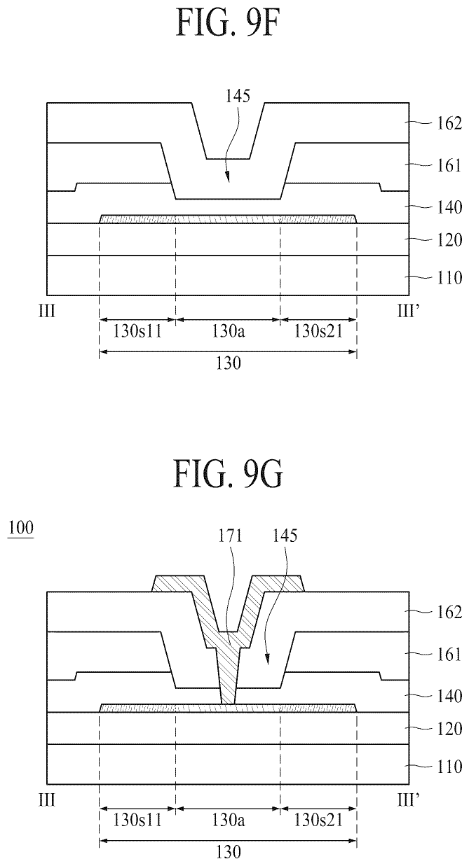

FIGS. 6A to 6G are process plan views showing a manufacturing process of a thin film transistor (100) according to one embodiment of the present disclosure. FIGS. 7A to 7G are cross-sectional views taken along line I-I′ of FIGS. 6A to 6G according to one embodiment of the present disclosure. FIGS. 8A to 8G are cross-sectional views taken along line II-II′ of FIGS. 6A to 6G according to one embodiment of the present disclosure. FIGS. 9A to 9G are cross-sectional views taken along line III-III′ of FIGS. 6A to 6G according to one embodiment of the present disclosure.

Method for manufacturing a thin film transistor (100) according to one embodiment of the present disclosure may include a step of forming an active material layer (130m), a step of sequentially forming a gate insulating film (140) and a first interlayer insulating film (161) on the active material layer (130m), a step of simultaneously etching the gate insulating film (140) and the first interlayer insulating film (161) to form a trench (145), a step of forming a gate electrode material layer (150m) on the trench (145) and the first interlayer insulating film (161), a step of doping the active material layer (130m) with dopant ions using the gate electrode material layer (150m) as a mask to form the active layer (130), a step of etching the gate electrode material layer (150m) to form a gate electrode (150), and a step of forming a second interlayer insulating film (161) on the gate electrode (150).

The plan views of FIGS. 6A to 6G correspond to the plan views of the thin film transistor (100) illustrated in FIG. 1, the cross-sectional views taken along line I-I′ of FIGS. 7A to 7G correspond to the cross-sectional views of the thin film transistor (100) illustrated in FIG. 2, the cross-sectional views taken along line II-II′ of FIGS. 8A to 8G correspond to the cross-sectional views of the thin film transistor (100) illustrated in FIG. 3, and the cross-sectional views taken along line III-III′ of FIGS. 9A to 9G correspond to the cross-sectional views of the thin film transistor (100) illustrated in FIG. 4.

Referring to FIGS. 6A, 7A, 8A, and 9A, a buffer layer (120) is formed on a base substrate (110), an active material layer (130m) is formed on the buffer layer (120), a gate insulating film (140) is formed on the active material layer (130m), and then a first interlayer insulating film (161) is formed on the gate insulating film (140). Only the active material layer (130m) is illustrated in the plan view of FIG. 6A.

The active material layer (130m) may include an oxide semiconductor material. The oxide semiconductor material may include, for example, at least one of an InZnO (IZO)-based oxide semiconductor material, an InGaO (IGO)-based oxide semiconductor material, an ITO (InSnO)-based oxide semiconductor material, an IGZO (InGaZnO)-based oxide semiconductor material, an IGZTO (InGaZnSnO)-based oxide semiconductor material, GZTO (GaZnSnO)-based oxide semiconductor material, GZO (GaZnO)-based oxide semiconductor material, ITZO (InSnZnO)-based oxide semiconductor material, and FIZO (FeInZnO)-based oxide semiconductor material.

Referring to FIGS. 6B, 7B, 8B, and 9B, the gate insulating film (140) and the first interlayer insulating film (161) can be etched simultaneously to form a trench (145). The trench (145) refers to a region formed by simultaneously patterning the gate insulating film (140) and the first interlayer insulating film (161). For example, the trench (145) is formed by simultaneously etching the gate insulating film (140) and the first interlayer insulating film (161).

Referring to FIGS. 6C, 7C, 8C, and 9C, a gate electrode material layer (150m) can be formed within a trench (145). Specifically, the gate electrode material layer (150m) can be formed on the trench (145) and the first interlayer insulating film (161). Thereafter, the active layer (130) can be formed by doping dopant ions into the active material layer (130m) using the gate electrode (150) as a mask.

At this time, the gate electrode material layer (150m) is not disposed on the entire upper surface of the trench (145) and the first interlayer insulating film (161).

The active layer (130) includes a first region (130c), a second region (130s1) disposed on one side of the first region (130c), and a third region (130s2). The first region (130c) may include a channel portion (130n), a first connecting portion (130a) disposed on one side of the channel portion (130n), and a second connecting portion (130b) connected to the other side of the channel portion (130n). The second region (130s1) may include a first dopant reduction portion (130s11), a second dopant reduction portion (130s13), and a first semiconductor portion (130s12) disposed between the first dopant reduction portion (130s11) and the second dopant reduction portion (130s13), and the third region (130s2) may include a third dopant reduction portion (130s21), a fourth dopant reduction portion (130s23), and a second semiconductor portion (130s22) disposed between the third dopant reduction portion (130s21) and the fourth dopant reduction portion (130s23).

Since the channel portion (130n), the first semiconductor portion (130s12), and the second semiconductor portion (130s22) are covered by the gate electrode (150), conductorization does not occur in the channel portion (130n). Since the first dopant reduction portion (130s11), the second dopant reduction portion (130s13), the third dopant reduction portion (130s21), and the fourth dopant reduction portion (130s23) are covered by the gate insulating film (140) and the first interlayer insulating film (161), the dopant ion concentrations of the first dopant reduction portion (130s11), the second dopant reduction portion (130s13), the third dopant reduction portion (130s21), and the fourth dopant reduction portion (130s23) may be lower than the dopant ion concentrations of the first connecting portion (130a) and the second connecting portion (130b). Since the first connecting portion (130a) and the second connecting portion (130b) are covered only by the gate insulating film (140) and not by the first interlayer insulating film (161), conductorization occurs in the first connecting portion (130a) and the second connecting portion (130b).

Referring to FIGS. 6D, 7D, 8D, and 9D, a gate electrode (150) can be formed by etching a gate electrode material layer (150m).

At this time, the gate electrode (150) is disposed inside the active layer (130) in a plane view. Additionally, the gate electrode (150) may be disposed inside a trench (145).

Referring to FIGS. 6E, 7E, 8E, and 9E, a second interlayer insulating film (162) can be formed on the gate electrode (150). The second interlayer insulating film (162) can cover the entirety of the gate electrode (150) and the first interlayer insulating film (161).

The second interlayer insulating film (162) is an insulating layer made of an insulating material. The second interlayer insulating film (162) may be made of an organic material, an inorganic material, or a laminate of an organic material layer and an inorganic material layer.

The second interlayer insulating film (162) may be made of the same material as the first interlayer insulating film (161) or may be made of a different material.

Referring to FIGS. 6F, 7F, 8F, and 9F, a gate connection electrode (152) can be formed that is disposed on the gate electrode (150) and is in contact with the gate electrode (150).

The gate connection electrode (152) is formed by etching the second interlayer insulating film (162). Although not shown in the drawing, the gate electrode (150) can be connected to the gate line (GL) through the gate connection electrode (152) (see FIG. 11).

Referring to FIGS. 6G, 7G, 8G, and 9G, a source electrode (171) and a drain electrode (172) can be formed on the second interlayer insulating film (162).

The source electrode (171) and the drain electrode (172) are each connected to the active layer (130) through a contact hole. Specifically, the source electrode (171) and the drain electrode (172) are connected to the active layer (130) by contacting the first connecting portion (130a) and the second connecting portion (130b).

FIG. 8H is an additional process cross-sectional view showing a manufacturing process of a thin film transistor according to one embodiment of the present disclosure.

According to one embodiment of the present invention, the source electrode (171) and the drain electrode (172) can be formed after the gate connection electrode (152) is formed. However, the present invention is not limited thereto, and the gate connection electrode (152), the source electrode (171), and the drain electrode (172) can be formed simultaneously (see FIG. 8h).

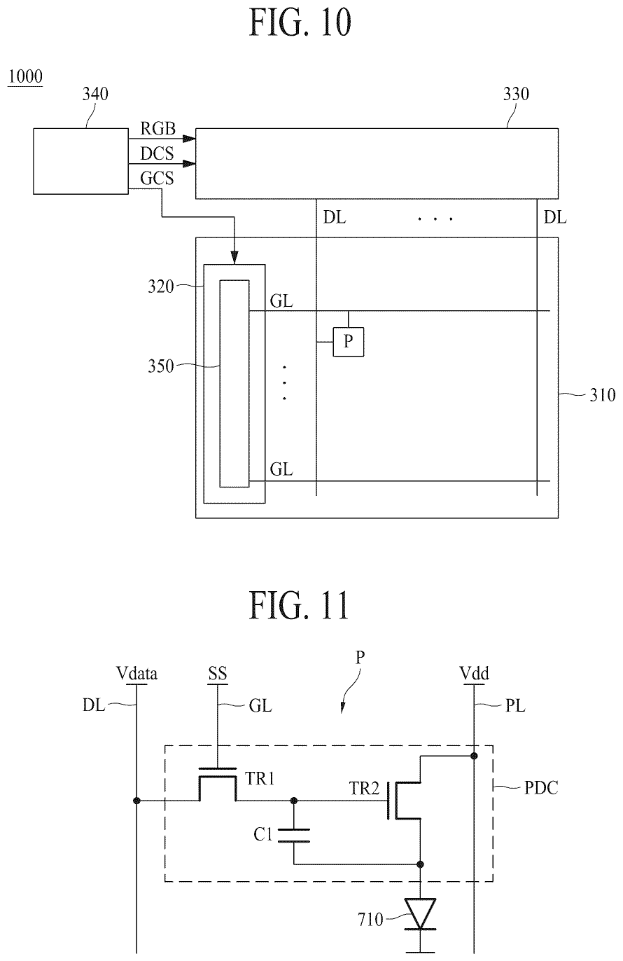

FIG. 10 is a schematic diagram illustrating a display apparatus 1000 according to further still another embodiment of the present disclosure.

As shown in FIG. 10, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistors 100, 200, 300, and 400. According to one embodiment of the present disclosure, the gate driver 320 may include the above-described thin film transistors 100.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the above-described thin film transistors 100.

FIG. 11 is a circuit view illustrating any one pixel P of FIG. 10 according to one embodiment.

The circuit view of FIG. 11 is an equivalent circuit view for the pixel P of the display apparatus 1000 that includes an organic light emitting diode (OLED) as a display element 710.

Referring to FIG. 11, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 11 includes a first thin film transistor TR1 that is a switching transistor and a second thin film transistor TR2 that is a driving transistor. The display apparatus 1000 according to another embodiment of the present disclosure may include at least one of the above-described thin film transistors 100.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

The pixel drive circuit (PDC) according to another embodiment of the present invention may be formed in a variety of structures other than those described above. The pixel drive circuit (PDC) may include, for example, three or more thin film transistors.

According to the present disclosure, the following advantageous effects may be obtained.

A thin film transistor according to one embodiment of the present disclosure can reduce an edge effect for an active layer by disposing a gate electrode within an active layer and increasing the resistivity of a second region and a third region.

A thin film transistor according to one embodiment of the present disclosure can reduce a fringe field between the first connecting portion and the second connecting portion by disposing the first connecting portion and the second connecting portion between the second region and the third region, respectively, and increasing the resistivity of the second region and the third region.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer;
a gate electrode overlapping at least partly with the active layer; and
a source electrode and a drain electrode connected to the active layer and spaced apart from each other,
wherein the active layer comprises:
a first region;
a second region on one side of the first region; and
a third region disposed on another side of the first region,
wherein when a direction connecting the source electrode and the drain electrode is a first direction and a direction perpendicular to the first direction is a second direction, the first region, the second region, and the third region are disposed along the second direction,
wherein the first region comprises:
a channel portion overlapping the gate electrode;
a first connecting portion on one side of the channel portion; and
a second connecting portion on another side of the channel portion,
wherein the second region includes a first dopant reduction portion and a second dopant reduction portion,
wherein the third region includes a third dopant reduction portion and a fourth dopant reduction portion, and
wherein the gate electrode is disposed inside the active layer in a plane view, and
wherein the first dopant reduction portion, the second dopant reduction portion, the third dopant reduction portion, and the fourth dopant reduction portion each have a resistivity that is higher than a resistivity of the first connecting portion and the second connecting portion.

2. The thin film transistor of claim 1, wherein the second region includes a first semiconductor portion between the first dopant reduction portion and the second dopant reduction portion,
wherein the third region includes a second semiconductor portion between the third dopant reduction portion and the fourth dopant reduction portion, and
wherein the first semiconductor portion and the second semiconductor portion has a resistivity that is higher than the resistivity of the first dopant reduction portion, the second dopant reduction portion, the third dopant reduction portion, and the fourth dopant reduction portion, respectively.

3. The thin film transistor of claim 2, wherein the gate electrode overlaps the first region and is between the first semiconductor portion and the second semiconductor portion in the plane view.

4. The thin film transistor of claim 1, wherein the first connecting portion is between the first dopant reduction portion and the third dopant reduction portion in the plane view,
wherein the second connecting portion is between the second dopant reduction portion and the fourth dopant reduction portion in the plane view.

5. The thin film transistor of claim 2, wherein the first dopant reduction portion and the second dopant reduction portion are spaced apart from each other with the first semiconductor portion therebetween,
wherein the first dopant reduction portion, the first semiconductor portion, and the second dopant reduction portion are disposed along the first direction,
wherein the third dopant reduction portion and the fourth dopant reduction portion are spaced apart from each other with the second semiconductor portion therebetween, and
wherein the third dopant reduction portion, the second semiconductor portion, and the fourth dopant reduction portion are disposed along the first direction.

6. The thin film transistor of claim 1, further comprising:
a gate insulating film on the active layer;
a first interlayer insulating film on the gate insulating film, and
a trench surrounded by the gate insulating film and the first interlayer insulating film.

7. The thin film transistor of claim 6, wherein the trench is formed by simultaneous etching of the gate insulating film and the first interlayer insulating film.

8. The thin film transistor of claim 6, wherein the gate electrode is within the trench, and the trench extends from the first connecting portion to the second connecting portion in the plane view.

9. The thin film transistor of claim 6, wherein at least a portion of the second region in the plane view overlaps the gate insulating film and the first interlayer insulating film,
wherein at least a portion of the third region in the plane view overlaps the gate insulating film and the first interlayer insulating film, and
wherein the first region overlaps the trench in the plane view.

10. The thin film transistor of claim 6, wherein a distance between an upper surface of the first region and an upper surface of the gate insulating film overlapping the first region is shorter than a distance between an upper surface of the second region and an upper surface of the gate insulating film overlapping the second region.

11. The thin film transistor of claim 1, wherein the gate electrode is non-overlapping with the second region and the third region in the plane view.

12. The thin film transistor of claim 1, wherein a dopant ion concentration of each of the first dopant reduction portion, the second dopant reduction portion, the third dopant reduction portion, and the fourth dopant reduction portion is lower than a dopant ion concentration of the first connecting portion and the second connecting portion.

13. The thin film transistor of claim 1, further comprising:
a gate connection electrode on the gate electrode and in contact with the gate electrode, and
wherein the gate electrode is connected to a gate line through the gate connection electrode.

14. A manufacturing method of a thin film transistor comprising:
forming an active material layer;
sequentially forming a gate insulating film and a first interlayer insulating film on the active material layer;
simultaneously etching the gate insulating film and the first interlayer insulating film to form a trench;
forming a gate electrode material layer on the trench and the first interlayer insulating film;
doping the active material layer with dopant ions using the gate electrode material layer as a mask to form an active layer;
etching the gate electrode material layer to form a gate electrode; and
forming a second interlayer insulating film on the gate electrode,
wherein the gate electrode is disposed inside the active layer in a plane view.

15. The manufacturing method of a thin film transistor of claim 14, wherein the active layer includes:
a first region;
a second region on one side of the first region; and
a third region disposed on another side of the first region,
wherein the first region includes:
a channel portion overlapping the gate electrode;
a first connecting portion on one side of the channel portion; and
a second connecting portion disposed on another side of the channel portion,
wherein the second region includes a first dopant reduction portion, a second dopant reduction portion, and a first semiconductor portion disposed between the first dopant reduction portion and the second dopant reduction portion,
wherein the third region includes a third dopant reduction portion, a fourth dopant reduction portion, and a second semiconductor portion disposed between the third dopant reduction portion and the fourth dopant reduction portion, and
wherein the first dopant reduction portion, the second dopant reduction portion, the third dopant reduction portion, and the fourth dopant reduction portion has a resistivity that is higher than a resistivity of the first connecting portion and the second connecting portion, respectively.

16. A display apparatus comprising the thin film transistor of claim 1.
